(19) United States
(12) Patent Application Publication
(10) Pub. No.: US 2025/0143011 A1
(43) Pub. Date: May 1, 2025

(54) PHOTODETECTOR WITH DISTRIBUTED BRAGG REFLECTOR AND METHODS OF FORMING THE SAME

(71) Applicant: Taiwan Semiconductor Manufacturing Company Limited, Hsinchu (TW)

(72) Inventors: Chen-Hao Chiang, Jhongli City (TW); Li-Weng Chang, Sanxia Township (TW); Jiun Yi Wu, Zhongli City (TW); Chen-Hua Yu, Hsinchu City (TW)

(21) Appl. No.: 18/496,969

(22) Filed: Oct. 30, 2023

(51) Int. Cl. H01L 31/0232; H01L 21/768; H01L 31/028

(52) U.S. Cl. CPC H10F 77/413; H01L 21/76829; H10F 77/122

(57) ABSTRACT

A semiconductor device includes: a photodiode including a germanium material portion laterally extending along a first horizontal direction, a p-doped silicon portion, and an n-doped silicon portion; and a distributed Bragg reflector including multiple periodic repetitions of a unit layer stack including a first material layer and a second material layer, wherein interfaces between vertically-extending portions of material layers within the distributed Bragg reflector are perpendicular to the first horizontal direction, and wherein the distributed Bragg reflector is in contact with the germanium material portion.

### BACKGROUND

A photodetector may be a semiconductor device that converts incident photons into an electrical signal. Photodetectors are utilized in various applications such as light detection, LIDAR, optical communications, cameras, etc. An ideal germanium p-i-n photodetector should exhibit high responsivity, low dark current, and high bandwidth. However, there is typically a trade-off between high responsivity and low dark current (or high bandwidth) in germanium p-i-n photodetectors. For example, optical applications (such as O-band applications using light having a wavelength of 1,550 nm) utilize an extended photodiode length to provide high responsivity, which increases dark current and reduces the bandwidth. Thus, enhancement of optical absorption efficiency is desirable to provide improve performance of photodetectors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are various views of an exemplary structure after formation of p-doped silicon portions and n-doped silicon portions according to an embodiment of the present disclosure. FIG. 1A is a top-down view. FIG. 1B is a vertical cross-sectional view along the vertical plane B-B′ of FIG. 1A. FIG. 1C is a vertical cross-sectional view along the vertical plane C-C′ of FIG. 1A. FIG. 1D is a vertical cross-sectional view along the vertical plane D-D′ of FIG. 1A.

FIGS. 2A-2D are various views of an exemplary structure after patterning a top silicon layer into a silicon waveguide and a silicon material matrix and formation of a shallow trench isolation structure according to an embodiment of the present disclosure. FIG. 2A is a top-down view. FIG. 2B is a vertical cross-sectional view along the vertical plane B-B′ of FIG. 2A. FIG. 2C is a vertical cross-sectional view along the vertical plane C-C′ of FIG. 2A. FIG. 2D is a vertical cross-sectional view along the vertical plane D-D′ of FIG. 2A.

FIGS. 3A-3C are various views of an exemplary structure after formation of a dielectric capping layer according to an embodiment of the present disclosure. FIG. 3A is a top-down view. FIG. 3B is a vertical cross-sectional view along the vertical plane B-B′ of FIG. 3A. FIG. 3C is a vertical cross-sectional view along the vertical plane C-C′ of FIG. 3A.

FIGS. 4A-4C are various views of an exemplary structure after formation of a trench in a distributed Bragg reflector region according to an embodiment of the present disclosure. FIG. 4A is a top-down view. FIG. 4B is a vertical cross-sectional view along the vertical plane B-B′ of FIG. 4A. FIG. 4C is a vertical cross-sectional view along the vertical plane C-C′ of FIG. 4A.

FIGS. 5A-5C are various views of an exemplary structure after formation of distributed Bragg reflector material layers according to an embodiment of the present disclosure. FIG. 5A is a top-down view. FIG. 5B is a vertical cross-sectional view along the vertical plane B-B′ of FIG. 5A. FIG. 5C is a vertical cross-sectional view along the vertical plane C-C′ of FIG. 5A.

FIGS. 6A-6C are various views of an exemplary structure after patterning the distributed Bragg reflector material layers according to an embodiment of the present disclosure. FIG. 6A is a top-down view. FIG. 6B is a vertical cross-sectional view along the vertical plane B-B′ of FIG. 6A. FIG. 6C is a vertical cross-sectional view along the vertical plane C-C′ of FIG. 6A.

FIGS. 7A-7C are various views of an exemplary structure after formation of a laterally-extending cavity according to an embodiment of the present disclosure. FIG. 7A is a top-down view. FIG. 7B is a vertical cross-sectional view along the vertical plane B-B′ of FIG. 7A. FIG. 7C is a vertical cross-sectional view along the vertical plane C-C′ of FIG. 7A.

FIGS. 8A-8D are various views of an exemplary structure after formation of a germanium material portion and a silicon capping layer according to an embodiment of the present disclosure. FIG. 8A is a top-down view. FIG. 8B is a vertical cross-sectional view along the vertical plane B-B′ of FIG. 8A. FIG. 8C is a vertical cross-sectional view along the vertical plane C-C′ of FIG. 8A. FIG. 8D is a horizontal cross-sectional view of the exemplary structure along the horizontal plane D-D′ of FIGS. 8B and 8C.

FIGS. 9A-9C are various views of an exemplary structure after formation of a dielectric cover layer, a contact-level dielectric layer, and contact via structures according to an embodiment of the present disclosure. FIG. 9A is a top-down view. FIG. 9B is a vertical cross-sectional view along the vertical plane B-B′ of FIG. 9A. FIG. 9C is a vertical cross-sectional view along the vertical plane C-C′ of FIG. 9A.

FIG. 10 is a vertical cross-sectional view of an alternative configuration of the exemplary structure according to an embodiment of the present disclosure.

FIG. 11 is a process flow diagram illustrating an exemplary process sequence for forming a semiconductor structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to an aspect of the present disclosure, a photodetector having enhanced light sensitivity at a specific wavelength is provided. A distributed Bragg reflector (DBR) providing total internal reflection (TIR) at the specific wavelength is formed on one side of the photodetector, which is the opposite side of the photodetector to which a waveguide is connected. The TIR provided by the DBR may allow more light to be absorbed by the photodetector at a resonance wavelength of the DBR, thereby increasing its light absorption efficiency at the resonance wavelength. Further, the light-reflecting geometry of the photodetector of various embodiments disclosed herein may provide a longer optical path. Thus, the various embodiments may provide for a reduction of the length of the photodetector. The reduction in the length of the photodetector may also reduce the dark current (i.e., the background current generated in the absence of incident light), and increases the bandwidth of the photodetector by reducing the capacitance of the photodetector. Various aspects of embodiments of the present disclosure are now described with reference to accompanying drawings.

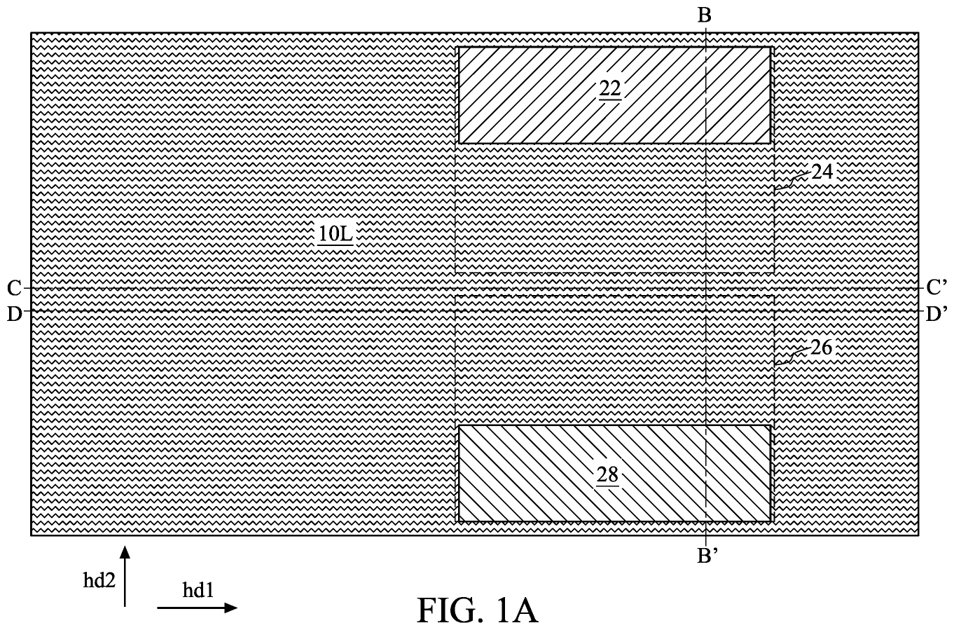

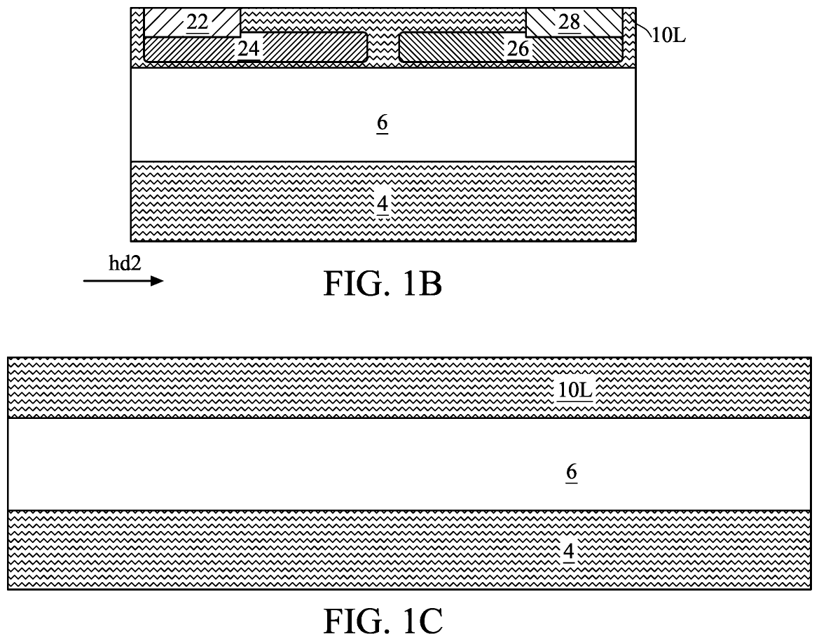

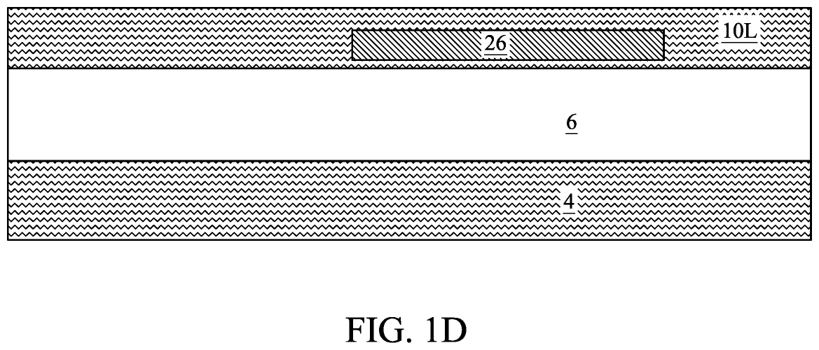

Referring to FIGS. 1A-1D, an exemplary structure according to an embodiment of the present disclosure is illustrated, which comprises a silicon-on-insulator (SOI) substrate including a stack of a handle substrate 4, a buried insulating layer 6, and a top silicon layer 10L. The top silicon layer 10L may comprise single crystalline silicon, and may have a thickness in a range from 200 nm to 600 nm, although lesser and greater thicknesses may also be used. The top silicon layer 10L may be intrinsic, or may includes electrical dopants at a low atomic concentration such as an atomic concentration that is less than 1.0×10¹⁶/cm³, and/or less than 1.0×10¹⁵/cm³, and/or less than 1.0×10¹⁴/cm³. The buried insulating layer 6 may comprise silicon oxide, and may have a thickness in a range from 500 nm to 2,000 nm, although lesser and greater thicknesses may also be used.

Masked ion implantation processes may be performed to form buried doped silicon portions (24, 26) and surface doped silicon portions (22, 28). The buried doped silicon portions (24, 26) may comprise a first p-doped silicon portion 24 and a first n-doped silicon portion 26 that are vertically spaced from the horizontal plane including the top surface of the top silicon layer 10L. The surface doped silicon portions (22, 28) may comprise a second p-doped silicon portion 22 and a second n-doped silicon portion 28 that are formed beneath the top surface of the top silicon layer 10L.

The first p-doped silicon portion 24 includes p-type electrical dopants at an atomic concentration in a range from 1.0×10¹⁷/cm³ to 1.0×10²⁰/cm³, such as from 1.0×10¹⁸/cm³ to 5.0×10¹⁹/cm³, although lesser and greater atomic concentrations may also be used. The first n-doped silicon portion 26 includes n-type electrical dopants at an atomic concentration in a range from 1.0×10¹⁷/cm³ to 1.0×10²⁰/cm³, such as from 1.0×10¹⁸/cm³ to 5.0×10¹⁹/cm³, although lesser and greater atomic concentrations may also be used. The second p-doped silicon portion 22 includes p-type electrical dopants at an atomic concentration in a range from 5.0×10¹⁹/cm³ to 2.0×10²¹/cm³, such as from 1.0×10²⁰/cm³ to 1.0×10²¹/cm³, although lesser and greater atomic concentrations may also be used. The second n-doped silicon portion 28 includes n-type electrical dopants at an atomic concentration in a range from 5.0×10¹⁹/cm³ to 2.0×10²¹/cm³, such as from 1.0×10²⁰/cm³ to 1.0×10²¹/cm³, although lesser and greater atomic concentrations may also be used.

The depth of the first p-doped silicon portion 24 and the first n-doped silicon portion 26, as measured from the top surface of the top silicon layer 10L, may be in a range from 10% to 80%, such as from 30% to 50%, of the thickness of the top silicon layer 10L. The thickness of the first p-doped silicon portion 24 and the first n-doped silicon portion 26 may be in a range from 20% 80%, such as from 30% to 60%, of the thickness of the top silicon layer 10L. The bottom surfaces of the first p-doped silicon portion 24 and the first n-doped silicon portion 26 may, or may not, contact the bottom surface of the top silicon layer 10L. The second p-doped silicon portion 22 may vertically extend from the top surface of the top silicon layer 10L to a top surface of the first p-doped silicon portion 24. The second n-doped silicon portion 28 may vertically extend from the top surface of the top silicon layer 10L to a top surface of the first n-doped silicon portion 26.

In one embodiment, each of the first p-doped silicon portion 24, the first n-doped silicon portion 26, the second p-doped silicon portion 22, and the second n-doped silicon portion 28 may laterally extend along a first horizontal direction hd1, which is the direction along which a silicon waveguide is subsequently patterned. In one embodiment, the first p-doped silicon portion 24 and the first n-doped silicon portion 26 may be laterally spaced from each other by a gap that laterally extends along the first horizontal direction hd1 and having a uniform spacing along a second horizontal direction hd2 that is perpendicular to the first horizontal direction hd1. The width of the gap between the first p-doped silicon portion 24 and the first n-doped silicon portion 26 is less than the width of a germanium material portion to be subsequently formed on the first p-doped silicon portion 24 and the first n-doped silicon portion 26. For example, the width of the gap between the first p-doped silicon portion 24 and the first n-doped silicon portion 26 may be in a range from 50 nm to 300 nm, such as from 80 nm to 200 nm, although lesser and greater widths may also be used. The length of the first p-doped silicon portion 24 and the first n-doped silicon portion 26 along the first horizontal direction hd1 may be in a range from 10 microns to 100 microns, although lesser and greater lengths may also be used.

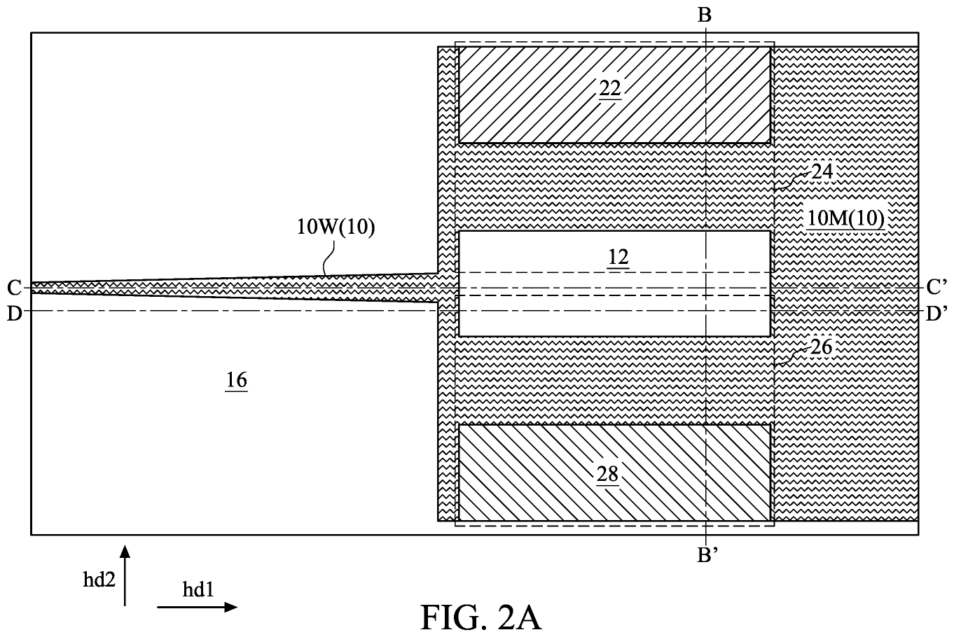

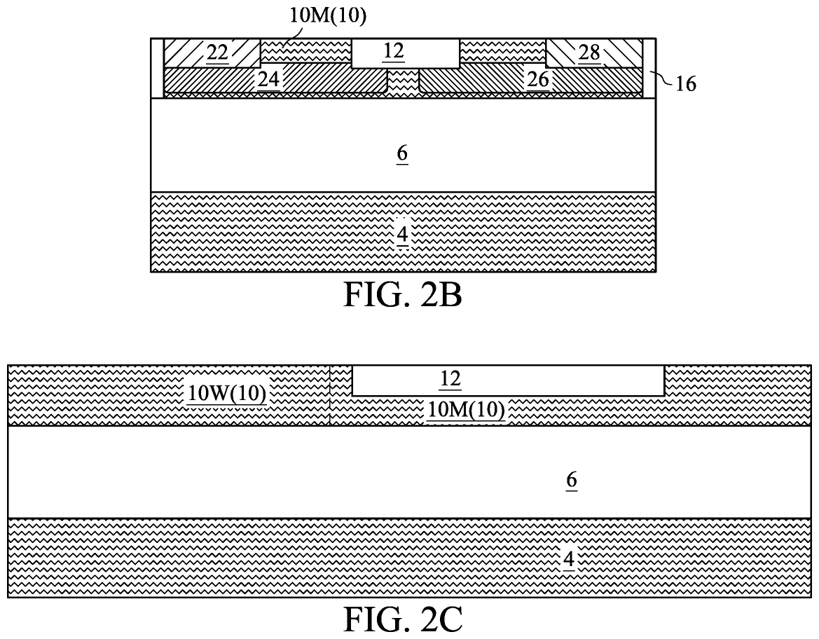

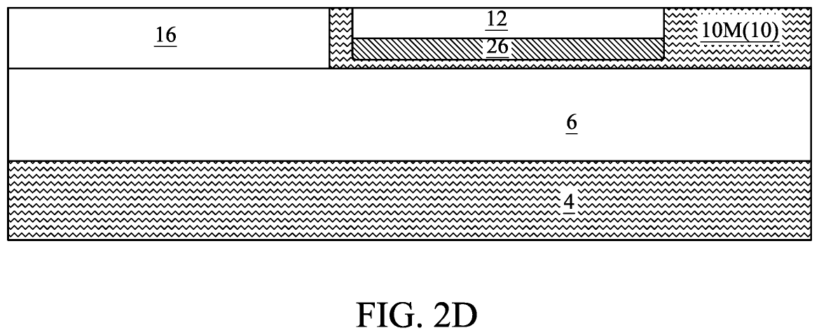

Referring to FIGS. 2A-2D, a first photoresist layer (not shown) may be applied over the top silicon layer 10L, and may be lithographically patterned to cover a region including the doped silicon portions (22, 24, 26, 28) and to cover a laterally-protruding strip portion of the top silicon layer 10L that laterally protrudes along the first horizontal direction hd1 from the gap between the first p-doped silicon portion 24 and the first n-doped silicon portion 26. A first anisotropic etch process may be performed to etch unmasked portions of the top silicon layer 10L, i.e., to etch portions of the top silicon layer 10L that are not covered by the patterned portions of the first photoresist layer.

The duration of the first anisotropic etch process may be selected such that a top surface of the buried insulating layer 6 is physically exposed in areas from which the material of the top silicon layer 10L is etched. Remaining portions of the top silicon layer 10L comprise a patterned silicon layer 10, which includes a silicon material matrix 10M that laterally surrounds each of the doped silicon portions (22, 24, 26, 28) and a silicon waveguide 10W. Generally, the first p-doped silicon portion 24 and the first n-doped silicon portion 26 are embedded within the silicon material matrix 10M. The silicon waveguide 10W is configured to guide photons of the resonance wavelength of a distributed Bragg reflector to be subsequently formed. In an illustrative example, the resonance wavelength may be any of commercially used optical communication wavelengths such as 850 nm, the range from 1,250 nm to 1,350 nm, 1,304 nm, 1,309 nm, 1310 nm, 1,490 nm, 1,550 nm, 1,590 nm, the range from 1,625 nm to 1,675 nm, etc. The silicon waveguide 10W may comprise a uniform width region that is distal from the silicon material matrix 10M and a tapered width region that is adjoined to the silicon material matrix 10M. The width and the horizontal cross-sectional profile of the silicon waveguide 10W may be selected to provide total internal reflection for the photons to be transmitted through the silicon waveguide 10W. The first photoresist layer may be subsequently removed, for example, by ashing. Generally, a combination of a silicon waveguide 10W and a silicon material matrix 10M may be formed by patterning the top silicon layer 10L that overlies the buried insulating layer 6.

A second photoresist layer (not shown) may be applied over the patterned silicon layer 10, and may be lithographically patterned to form a slit-shaped opening that overlies the gap between the first p-doped silicon portion 24 and the first n-doped silicon portion 26. The width of the slit-shaped opening may be greater than the width of the gap along the second horizontal direction hd2 at least by 50 nm, and preferably by more than 100 nm, and/or by more than 200 nm. The slit-shaped openings in the second photoresist layer may be formed between the area of the second p-doped silicon portion 22 and the area of the second n-doped silicon portion 28.

A second anisotropic etch process to etch a portion of the silicon material matrix 10M that is not masked by the second photoresist layer, i.e., the portion of the silicon material matrix 10M underlying the slit-shaped opening in the second photoresist layer. A line trench having a uniform width may be formed in an upper portion of the silicon material matrix 10M. The duration of the second anisotropic etch process may be selected such that strip-shaped edge portions of the first p-doped silicon portion 24 and the first n-doped silicon portion 26 are physically exposed to the line trench. Thus, the depth of the line trench (as measured from the horizontal plane including the top surface of the patterned silicon layer 10) may be greater than the depth of the top surfaces of the first p-doped silicon portion 24 and the first n-doped silicon portion 26, and may be less than the depth of the bottom surfaces of the first p-doped silicon portion 24 and the first n-doped silicon portion 26. The second photoresist layer may be subsequently removed, for example, by ashing.

A dielectric fill material such as silicon oxide may be deposited in the cavities formed by removal of the material of the top silicon layer 10L. The cavities include field cavities that are formed adjacent to the silicon waveguide 10W and the line trench that overlies the physically exposed surfaces of the first p-doped silicon portion 24 and the first n-doped silicon portion 26 and a recessed surface of the silicon material matrix 10M. Excess portions of the dielectric fill material may be removed from above the horizontal plane including the top surface of the patterned silicon layer 10 by performing a planarization process, which may comprise a chemical mechanical polishing process and/or a recess etch process. In some embodiments, a hard mask layer (not shown) may be formed above the top silicon layer 10L prior to formation of the cavities in the top silicon layer 10L, and may be used as a planarization stopping layer during the planarization process and may be subsequently removed selective to the materials of the patterned silicon layer 10 and the dielectric fill material.

The remaining portions of the dielectric fill material that fill the cavities in the patterned silicon layer 10 constitute shallow trench isolation structures (12, 16), which comprise, for example, a first shallow trench isolation structure 12 in contact with the first p-doped silicon portion 24 and the first n-doped silicon portion 26, and further comprise a second shallow trench isolation structure 16 in contact with sidewalls of the silicon waveguide 10W. Top surfaces of the shallow trench isolation structures (12, 16) may be coplanar with the top surface of the patterned silicon layer 10.

Generally, the silicon waveguide 10W may be formed over the buried insulating layer 6, and may laterally extend along the first horizontal direction hd1. The silicon material matrix 10M may be adjoined to an end portion of the silicon waveguide 10W, and embeds a first shallow trench isolation structure 12 that laterally extends along the first horizontal direction hd1 and aligned to the end portion of the silicon waveguide 10W along the second horizontal direction hd2. The first p-doped silicon portion 24 and the first n-doped silicon portion 26 are embedded within the silicon material matrix 10M, and contact a bottom surface of the first shallow trench isolation structure 12.

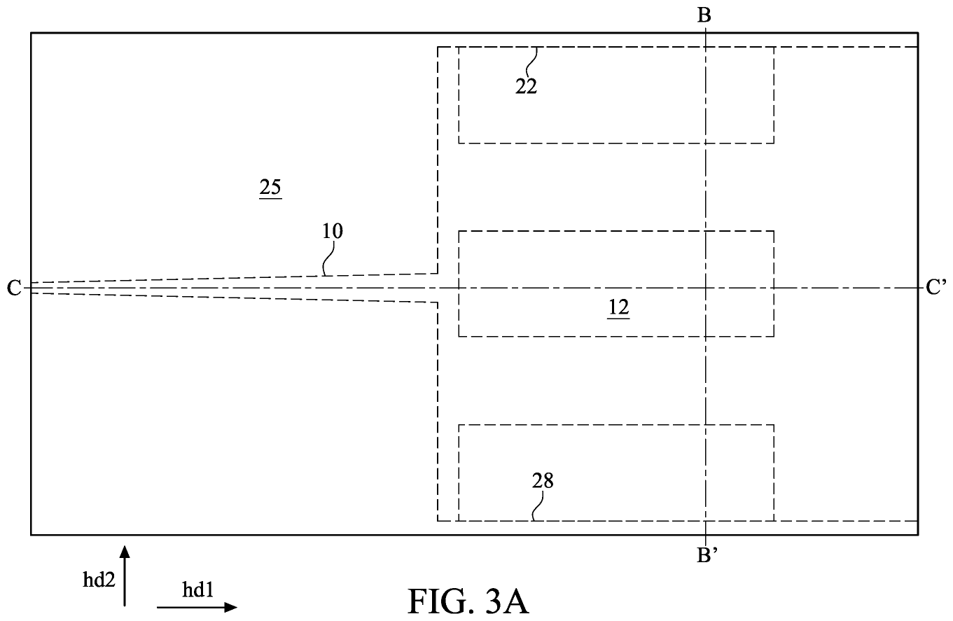

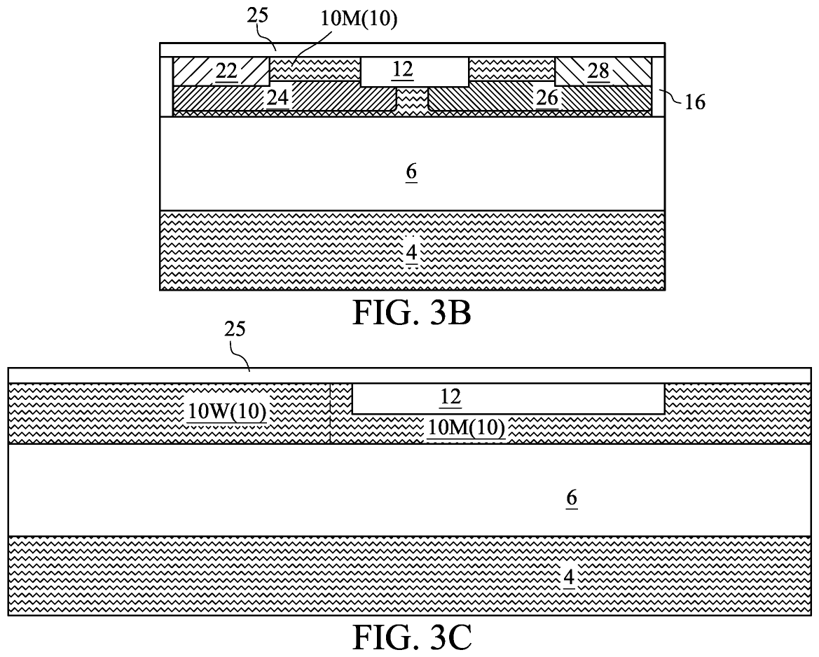

Referring to FIGS. 3A-3C, a dielectric capping material having a uniform thickness may be deposited over the patterned silicon layer 10 and the shallow trench isolation structures (12, 16) to form a dielectric capping layer 25. In one embodiment, the dielectric capping layer 25 comprises silicon oxide or silicon nitride. The thickness of the dielectric capping layer 25 may be in a range from 30 nm to 300 nm, such as from 60 nm to 150 nm, although lesser and greater thicknesses may also be used.

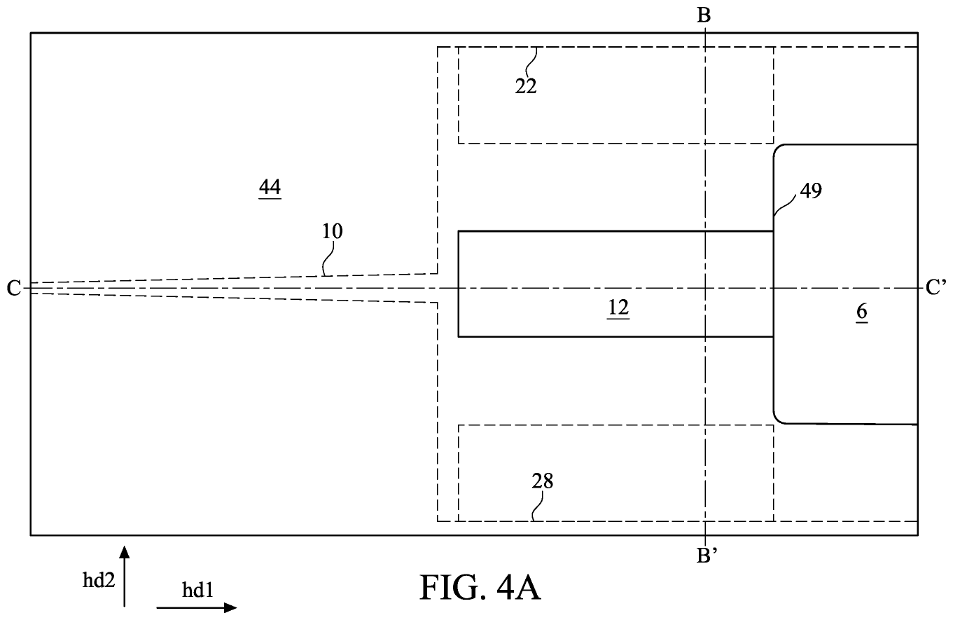

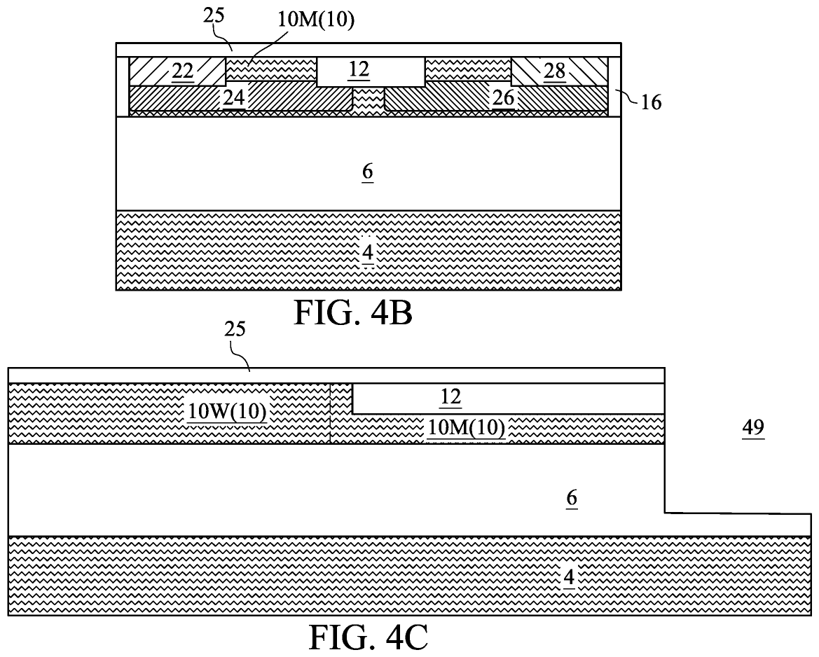

Referring to FIGS. 4A-4C, a photoresist layer (not shown) may be applied over the dielectric capping layer 25, and may be lithographically patterned to form an opening over an area of the silicon material matrix 10M that is adjacent to the first shallow trench isolation structure 12. In this embodiment, the patterned photoresist layer may have a straight edge that is parallel to the second horizontal direction hd2 and overlies an edge portion of the first shallow trench isolation structure 12. In one embodiment, the straight edge of the photoresist layer may have a lateral extent that is greater than the lateral extent of the combination of the second p-doped silicon portion 22 and the second n-doped silicon portion 28.

An anisotropic etch process may be performed to etch portions of the silicon material matrix 10M and at least an upper portion of the buried insulating layer 6 that are not masked by the patterned photoresist layer. A trench, which is herein referred to as a reflector-region trench 49, is formed in the portion of the silicon material matrix 10M and the buried insulating layer 6 that is not covered by the patterned photoresist layer. The reflector-region trench 49 comprises a straight vertical sidewall that is perpendicular to the first horizontal direction hd1. In one embodiment, the straight vertical sidewall may comprise a vertical surface segment of the first p-doped silicon portion 24, a vertical surface segment of the first n-doped silicon portion 26, a vertical surface segment of the silicon material matrix 10M, and a vertical surface segment of the buried insulating layer 6, and may optically comprise a vertical surface segment of the second p-doped silicon portion 22 and a vertical surface segment of the second n-doped silicon portion 28.

Generally, the depth of the reflector-region trench 49 may be greater than the thickness of the silicon material matrix 10M, and may, or may not, be greater than the sum of the thickness of the silicon material matrix 10M and the thickness of the buried insulating layer 6. If the depth of the reflector-region trench 49 is less than the sum of the thickness of the silicon material matrix 10M and the thickness of the buried insulating layer 6, a recessed surface of the buried insulating layer 6 may be the bottom surface of the reflector-region trench 49. If the depth of the reflector-region trench 49 is greater than the sum of the thickness of the silicon material matrix 10M and the thickness of the buried insulating layer 6, a recessed surface of the handle substrate 4 may be the bottom surface of the reflector-region trench 49. Generally, the reflector-region trench 49 may be formed by removing portions of the silicon material matrix 10M and the buried insulating layer 6.

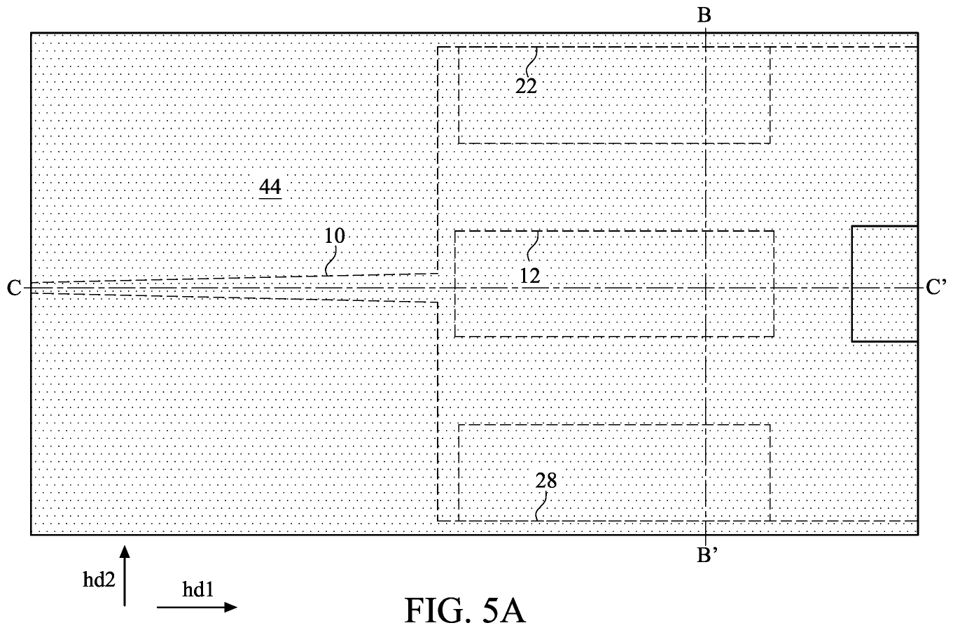

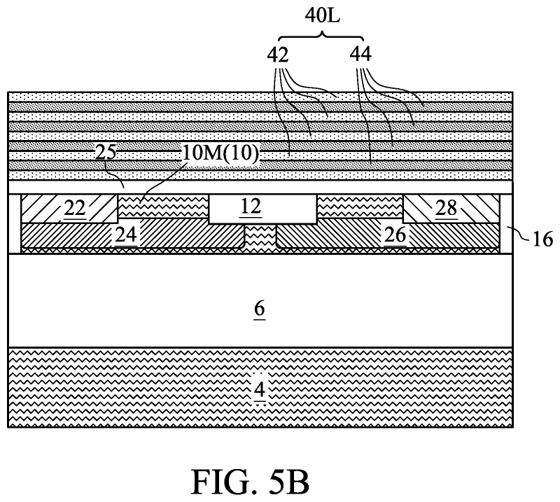

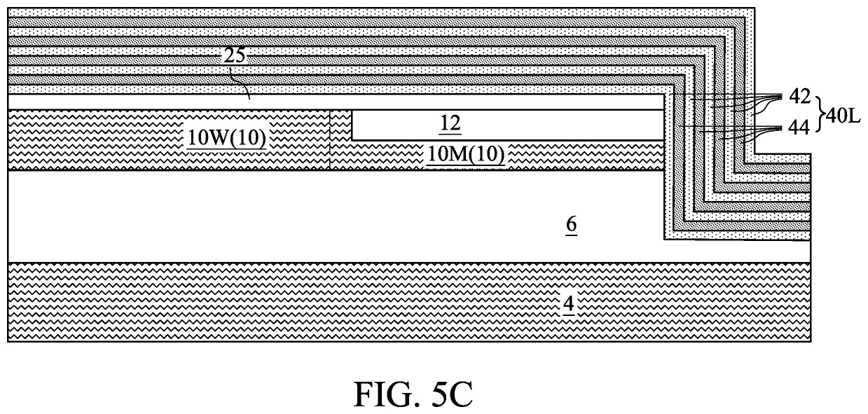

Referring to FIGS. 5A-5C, distributed Bragg reflector (DBR) material layers 40L may be formed over the dielectric capping layer 25 and the sidewalls and the bottom surface of the reflector-region trench 49. A distributed Bragg reflector (DBR) is an optical device including a periodic structure made up of alternating layers of materials with different refractive indices. These layers are carefully engineered to create constructive interference for a specific wavelength of light (which is referred to as a resonance wavelength), while providing low reflection or transmission for other wavelengths. A DBR may be used to reflect or filter specific wavelengths of light in a controlled and efficient manner. A DBR uses constructive interference of light waves. When light of the resonance wavelength passes through the periodic layers of the DBR, the light experiences multiple reflections at each interface between the layers. The thicknesses of the layers are designed to induce the reflected waves to constructively interfere align in phase at the resonance wavelength so that the DBR provides high reflectivity for the resonance wavelength.

The DBR material layers 40L may include multiple periodic repetitions (i.e., N periodic repetitions in which N is greater than 1) of a unit layer stack including a first material layer 42 and a second material layer 44 on a sidewall of the trench. The total number of repetitions of the unit layer stack may be in a range from 2 to 30, such as from 3 to 10, although a greater number of repetitions may also be used. In the illustrated example, the total number of repetitions is 4. If an instance of the first material layer 42 is an outermost material layer of the DBR material layers 40L, an unpaired instance of the first material layer 42 may be provided in addition to the multiple periodic repetitions of the unit layer stack on an opposite side of the instance of the first material layer 42 that functions as the outermost material layer. In other words, the DBR material layers 40L may comprise two instances of the first material layer 42 as two outermost material layers. The reflectivity of the DBR depends on the number of periods as well as the refractive indices of the materials.

In one embodiment, the thickness of the each instance of the first material layer 42 and each instance of the second material layer 44 may be set at λ/(4n) to achieve high reflectivity for the layer stack including the DBR material layers 40L. In this embodiment, λ is the wavelength in free space and n is the refractive index of the respective material layer, which may be the first material layer 42 or the second material layer 44. If each first material layer 42 has a first refractive index n₁ and if each second material layer 44 has a second refractive index n₂, the first thickness t1 of each first material layer 42 may be given by λ/(4n₁), and the second thickness t2 of each second material layer 44 may be given by λ/(4n₂).

In an illustrative example, if the light to be reflected by the DBR material layers 40L has a wavelength of 1,550 nm in vacuum, and if each instance of the first material layer 42 comprises silicon oxide having a first refractive index n₁ of 1.444, the first thickness of each instance of the first material layer 41 may be given by 1,550 nm/(4×1.444)=268 nm. If the light to be reflected by the DBR material layers 40L has a wavelength of 1,550 nm in vacuum, and if each instance of the first material layer 42 comprises aluminum oxide having a first refractive index n₁ of 1.746, the first thickness of each instance of the first material layer 41 may be given by 1,550 nm/(4×1.746)=222 nm. If the light to be reflected by the DBR material layers 40L has a wavelength of 1,550 nm in vacuum, and if each instance of the second material layer 44 comprises silicon nitride having a second refractive index n₂ of 1.983, the second thickness of each instance of the first material layer 41 may be given by 1,550 nm/(4×1.983)=195 nm. If the light to be reflected by the DBR material layers 40L has a wavelength of 1,550 nm in vacuum, and if each instance of the second material layer 44 comprises aluminum nitride having a second refractive index n₂ of 2.12, the second thickness of each instance of the first material layer 41 may be given by 1,550 nm/(4×2.12)=1183 nm.

In embodiments in which a set of DBR material layers 40L consists of N repetitions of a pair of a first material layer 42 having the first refractive index n₁ and the first thickness given by λ/(4n₁) and a second material layer 44 having the second refractive index n₂ and the second thickness given by λ/(4n₂), the reflectivity R of such a set of DBR material layers 40L for light having a vacuum wavelength λ is given by:

$$R = {⌈ \frac{1 - \frac{{{n}_{1}}^{2}}{{n}_{0} {n}_{3}} {( \frac{{n}_{1}}{{n}_{2}} )}^{2 N}}{1 + \frac{{{n}_{1}}^{2}}{{n}_{0} {n}_{3}} {( \frac{{n}_{1}}{{n}_{2}} )}^{2 N}} ⌉}^{2} ,$$

in which n₀ stands for the refractive index of a material layer that is placed in front of the set of DBR material layers 40L, and n₃ stands for the refractive index of a material layer that is placed behind the set of DBR material layers 40L.

In embodiments in which a set of DBR material layers 40L comprises of N repetitions of a pair of a first material layer 42 having the first refractive index n₁ and the first thickness given by λ/(4n₁) and a second material layer 44 having the second refractive index n₂ and the second thickness given by λ/(4n₂) and additionally comprises another instance of the first material layer 42, the reflectivity R of such a set of DBR material layers 40L for light having a vacuum wavelength λ is given by:

$$R = {⌈ \frac{1 - \frac{{n}_{3}}{{n}_{0}} {( \frac{{n}_{1}}{{n}_{2}} )}^{2 N}}{1 + \frac{{n}_{3}}{{n}_{0}} {( \frac{{n}_{1}}{{n}_{2}} )}^{2 N}} ⌉}^{2} ,$$

in which n₀ stands for the refractive index of a material layer that is placed in front of the set of DBR material layers 40L, and n₃ stands for the refractive index of a material layer that is placed behind the set of DBR material layers 40L.

While the present disclosure is illustrated using an embodiment in which the reflector-region trench 49 has a bottom surface that is a recessed surface of the buried insulating layer 6, embodiments are expressly contemplated herein in which the reflector-region trench 49 has a bottom surface that is a recessed surface of the handle substrate 4. In this embodiment, a bottommost layer of the DBR material layers 40L may contact a recessed horizontal surface of the handle substrate 4.

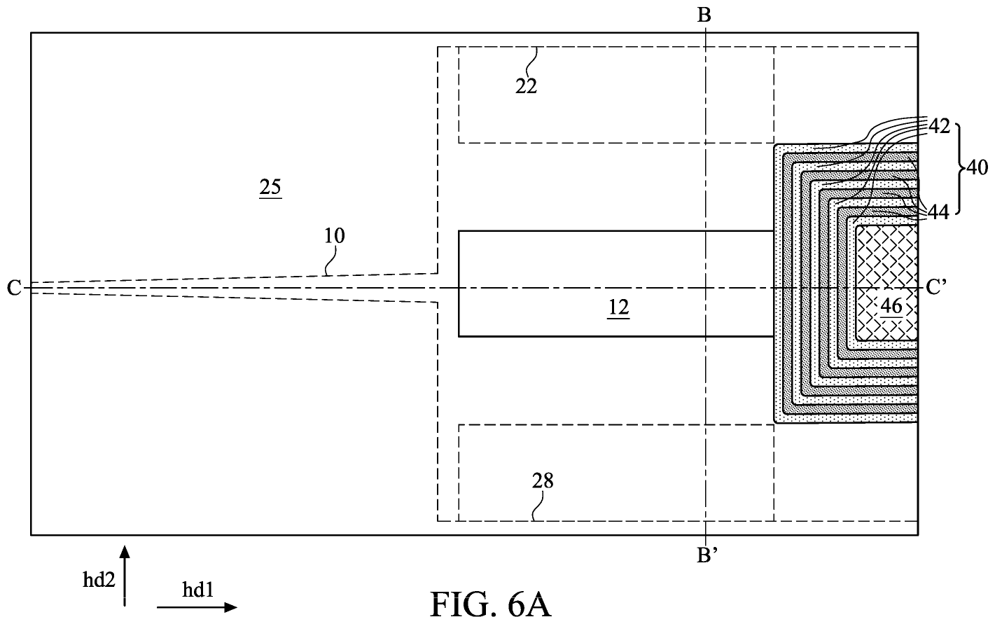

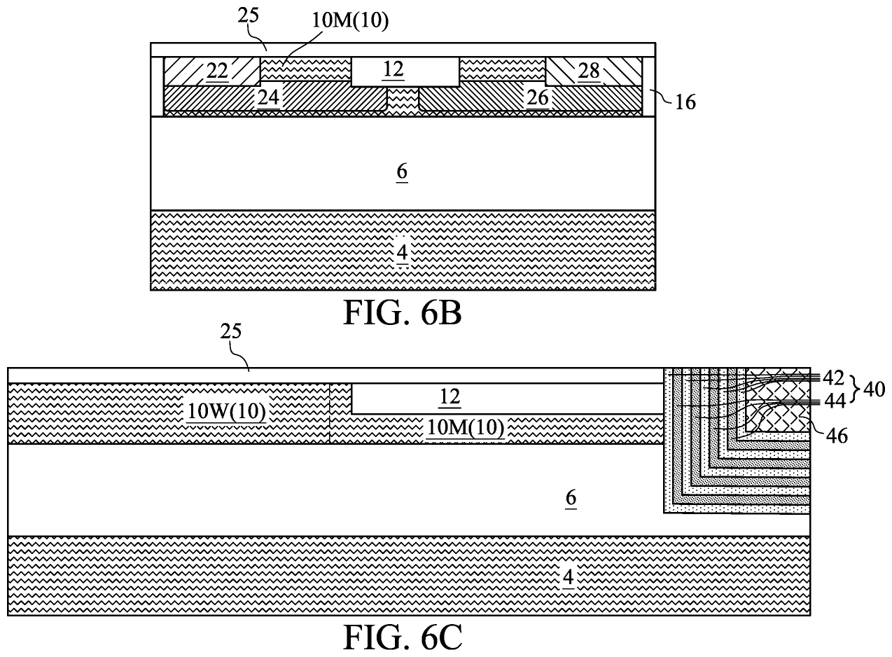

Referring to FIGS. 6A-6C, a fill material having a high refractive index such as polysilicon may be deposited over the DBR material layers 40L such that all volumes of the reflector-region trench 49 underlying the horizontal plane including the top surface of the dielectric capping layer 25 are filled with the materials of the DBR material layers 40L and the fill material. A planarization process may be performed to remove portions of the DBR material layers 40L and the fill material that are located above the horizontal plane including the top surface of the dielectric capping layer 25. Generally, any planarization process may be used to remove the portions of the DBR material layers 40L and the fill material that are located above the horizontal plane including the top surface of the dielectric capping layer 25. For example, the planarization process may comprise a chemical mechanical polishing process and/or a recess etch process.

Remaining portions of the DBR material layers 40L that fill the reflector-region trench 49 constitutes a distributed Bragg reflector (DBR) 40. A remaining portion of the fill material that fills the remainder of the reflector-region trench 49 constitutes a DBR backing structure 46. In one embodiment, the DBR backing structure 46 may comprise a high refractive index material such as polysilicon, which has a refractive index of about 3.5. In one embodiment, the thickness of the DBR backing structure 46 may be greater than the thickness of the first shallow trench isolation structure 12. Top surfaces of the DBR 40 and the DBR backing structure 46 may be coplanar with the top surface of the dielectric capping layer 25.

Generally, a dielectric capping layer 25 may be formed over the silicon material matrix 10M, and the multiple periodic repetitions of the unit layer stack of the first material layer 42 and the second material layer 44 may be formed in the reflector-region trench 49 and over the dielectric capping layer 25. Portions of the multiple periodic repetitions of the unit layer stack may be removed from above the horizonal plane including the top surface of the dielectric capping layer 25. A distributed Bragg reflector (DBR) 40 may be formed, which includes remaining portions of the multiple periodic repetitions of the unit layer stack including the first material layer 42 and the second material layer 44. The DBR may be formed directly on a sidewall of the reflector-region trench 49. In one embodiment, vertical interfaces between vertically-extending portions of material layers (42, 44) within the distributed Bragg reflector 40 may be perpendicular to the first horizontal direction hd1.

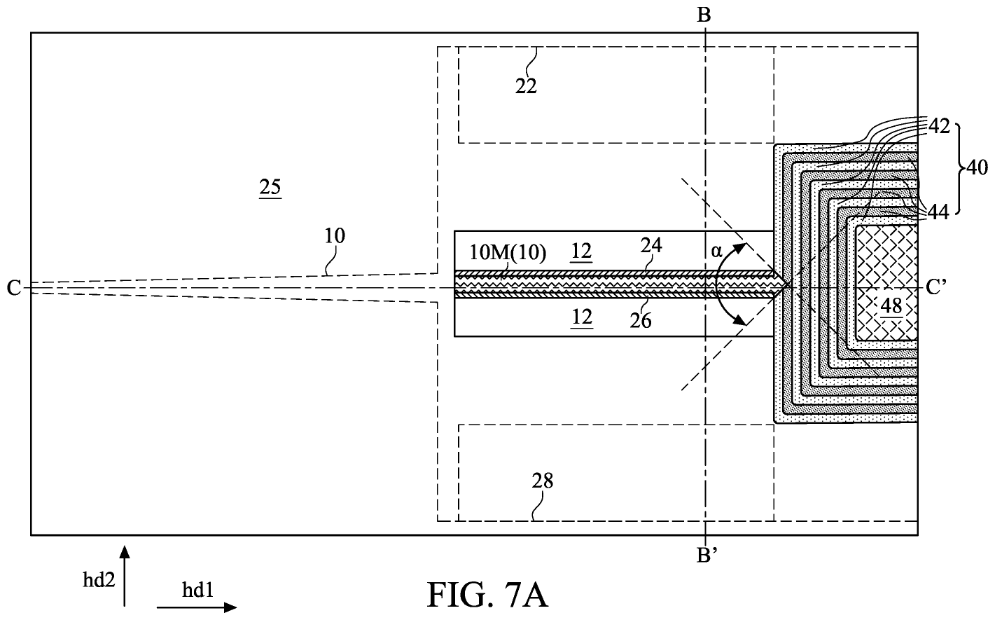

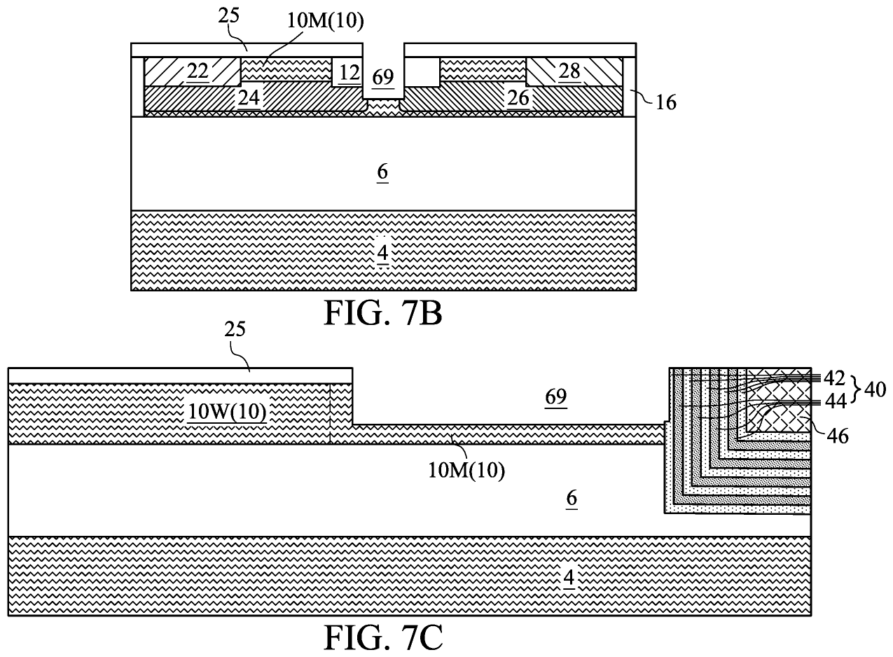

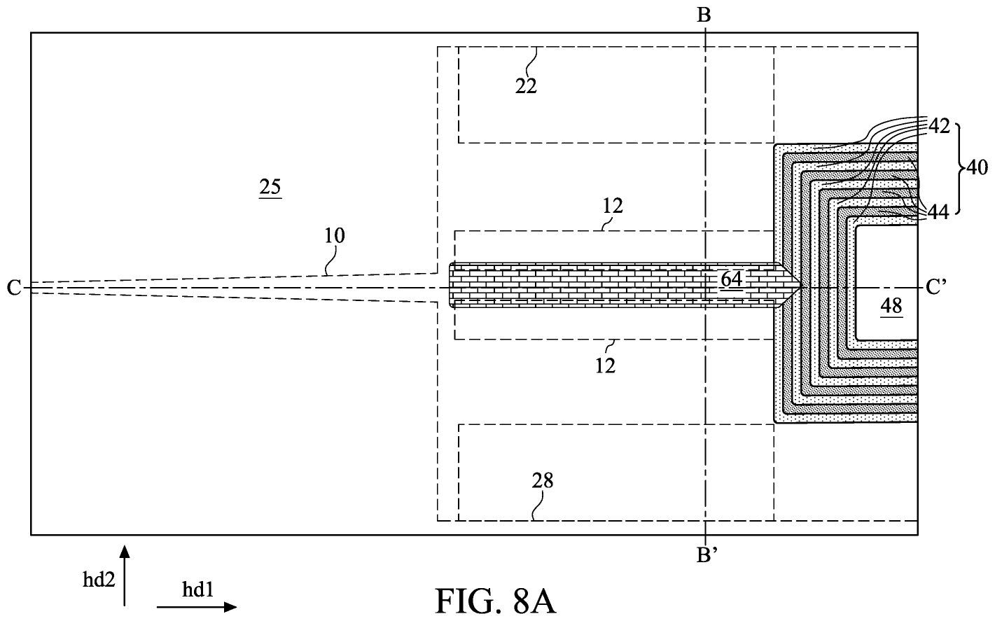

Referring to FIGS. 7A-7C, a photoresist layer (not shown) may be applied over the dielectric capping layer 25, the DBR 40, and the DBR backing structure 46, and may be lithographically patterned a slit-shaped opening that extends over the first shallow trench isolation structure 12 along the first horizontal direction hd1. The slit-shaped opening may have a triangular lateral protrusion that crosses over the vertical interface between the silicon material matrix 10M and the DBR 40.

An anisotropic etch process may be performed to etch unmasked portions of the dielectric capping layer 25, the first shallow trench isolation structure 12, and a peripheral portion of the DBR 40 that are not masked by the patterned photoresist layer. In one embodiment, the anisotropic etch process may etch the material of the first shallow trench isolation structure 12 selective to the material of the silicon material matrix 10M until surfaces of the silicon material matrix 10M, the first p-doped silicon portion 24, and the first n-doped silicon portion 26 are exposed. A laterally-extending cavity 69 may be formed in the volume from which the materials of the dielectric capping layer 25, the first shallow trench isolation structure 12, and the peripheral portion of the DBR 40 are etched. Optionally, the anisotropic etch process may comprise an overetch step that vertically extends the laterally-extending cavity 69.

The laterally-extending cavity 69 divides the first shallow trench isolation structure 12 as formed at the processing steps described with reference to FIGS. 2A-2D into two disjoined first shallow trench isolation structures 12 that are laterally spaced apart along the second horizontal direction hd2 by a uniform spacing, which is the width of the laterally-extending cavity 69. The laterally-extending cavity 69 may be formed between the silicon waveguide 10W and the distributed Bragg reflector 40 such that a sidewall of the distributed Bragg reflector 40 is exposed to the laterally-extending cavity 69, and the silicon waveguide 10W is laterally spaced from the laterally-extending cavity 69 by a remaining portion of the silicon material matrix 10M.

In one embodiment, the laterally-extending cavity 69 laterally extends along the first horizontal direction hd1 and has an end wall that is aligned to the silicon waveguide 10W. The lateral thickness of the portion of the silicon material matrix 10M along the first horizontal direction hd1 which remains between the laterally-extending cavity 69 and the silicon waveguide 10W may be in a range from 30 nm to 600 nm, such as from 60 nm to 300 nm, although lesser and greater lateral thicknesses may also be used. In other words, the distance between the silicon waveguide 10W and the end wall of the laterally-extending cavity 69 may be in a range from 30 nm to 600 nm, such as from 60 nm to 300 nm, although lesser and greater distances may also be used.

In one embodiment, the width of the laterally-extending cavity 69 along the second horizontal direction hd2 may be the same as, or may be substantially the same as, the width of a most proximal portion of the silicon waveguide 10W. A strip-shaped horizontal surface segment of the first p-doped silicon portion 24, a strip-shaped horizontal surface segment of the first n-doped silicon portion 26, and a strip-shaped horizontal surface segment of the silicon material matrix 10M may be physically exposed at the bottom of the laterally-extending cavity 69.

According to an embodiment of the present disclosure, the laterally-extending cavity 69 may comprise a notched end portion that cuts through an instance of the first material layer 42. In one embodiment, the notched end portion has a triangular horizontal cross-sectional shape. The lateral dimension of the triangular horizontal cross-sectional shape of the notched end portion of the laterally-extending cavity along the first horizontal direction hd1 may be the same as the thickness of a first material layer 42 in the DBR 40. Specifically, two sides of the triangular shape may be tilted relative to the first horizontal direction hd1 by a respective angle in a range from 40 degrees to 50 degrees (such as 45 degrees), and may have a lateral dimension along the first horizontal direction hd1 that equals the thickness of the most proximal first material layer 42 within the DBR 40. Further, the total lateral extent of the two sides of the triangular shape along the second horizontal direction hd2 may equal the spacing between the two first shallow trench isolation structures 12, i.e., the width of the portion of the laterally-extending cavity 69 having a uniform width. In one embodiment, the laterally-extending cavity 69 comprises an angled protrusion portion that protrudes laterally into the distributed Bragg reflector 40 such that two angled vertical sidewalls of the laterally-extending cavity 69 comprise sidewalls of the most proximal first material layer 42, and are adjoined to each other at an angle a in a range from 80 degrees to 100 degrees in a plan view. Each angled vertical sidewall of the laterally-extending cavity 69 may comprise an angled vertical sidewall of the most proximal first material layer 42, and may laterally extend from an interface between the most proximal first material layer 42 and the silicon material matrix 10M to an interface between the most proximal first material layer 42 and the most proximal second material layer 44.

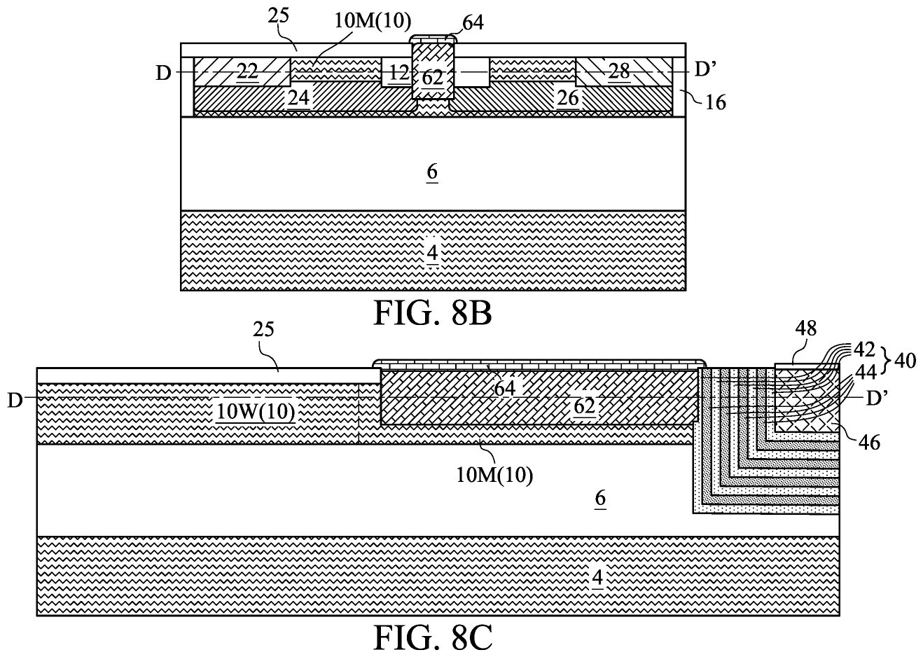

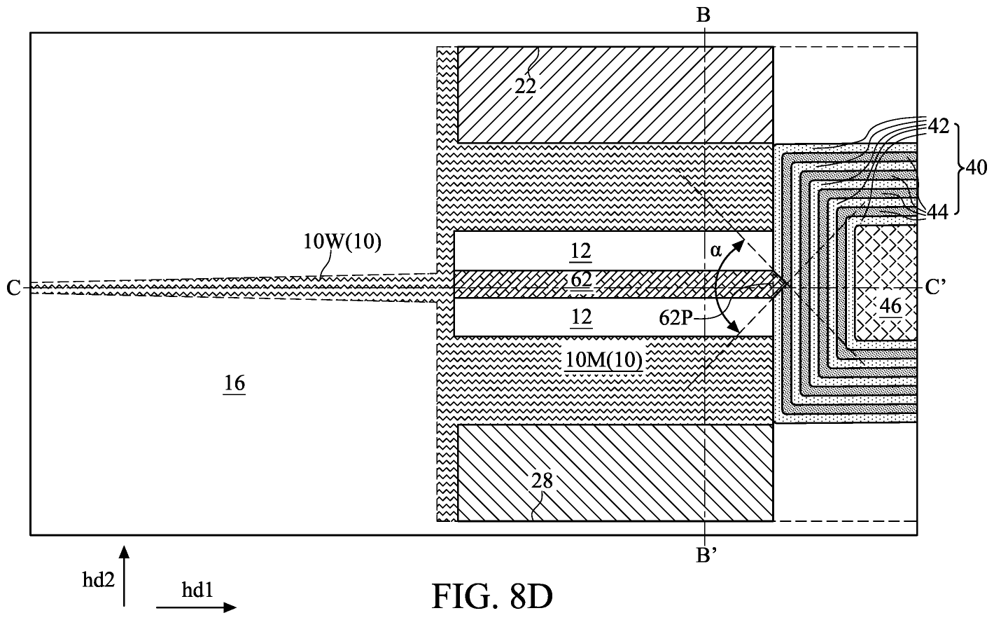

Referring to FIGS. 8A-8D, in embodiments in which the DBR backing structure 46 comprises a semiconductor material such as polysilicon, a surface oxidation process may be performed to convert a physically exposed surface portion of the DBR backing structure 46 into a dielectric liner 48, which may comprise a silicon oxide liner. Physically exposed surface portions of the silicon material matrix 10M at the bottom of the laterally-extending cavity 69 may be converted into a sacrificial silicon oxide liner (not shown). A photoresist layer (not shown) may be applied over the dielectric capping layer 25, the DBR 40, and the dielectric liner 48, and may be lithographically patterned to remove the portion of the photoresist layer from inside, and from above, the laterally-extending cavity 69 while covering the dielectric liner 48. An isotropic etch process that etches silicon oxide may be performed to remove the sacrificial silicon oxide liner from underneath the laterally-extending cavity 69. If the DBR backing structure 46 comprises a dielectric material, formation of a dielectric liner 48 may be omitted.

A selective germanium deposition process may be performed to grow a germanium material portion 62 from physically exposed surfaces of the silicon material matrix 10M, the first p-doped silicon portion 24, and the first n-doped silicon portion 26. In one embodiment, the selective germanium deposition process may comprise a selective germanium epitaxy process. A selective germanium deposition process may grow germanium from physically exposed semiconductor surfaces while suppressing growth of germanium from dielectric surfaces. For example, a germanium precursor gas such as germane or digermane may be flowed concurrently with, or alternately with, an etchant gas such as gas phase hydrogen chloride. The growth rate of germanium from semiconductor surfaces is greater than the growth rate of germanium from dielectric surfaces. Selective growth of germanium only from semiconductor surfaces may be effected by setting the flow rate of the etchant gas such that the etch rate of the etchant gas is greater than the growth rate of germanium from dielectric surfaces and is less than the growth rate of germanium from semiconductor surfaces. Thus, germanium may grow only from the physically exposed surfaces of the silicon material matrix 10M, the first p-doped silicon portion 24, and the first n-doped silicon portion 26.

A germanium material portion 62 may be formed in the laterally-extending cavity 69. The germanium material portion 62 may grow from, and may be formed on, a peripheral region of the first p-doped silicon portion 24 and on a peripheral portion of the first n-doped silicon portion 26. In one embodiment, the duration of the selective germanium deposition process may be selected such that a horizontal top surface of the germanium material portion 62 is formed above the horizontal plane including the bottom surface of the dielectric capping layer 25, and below the horizontal plane including the top surface of the dielectric capping layer 25. In this embodiment, the horizontal top surface of the germanium material portion 62 contacts a sidewall of the dielectric capping layer 25. In one embodiment, each instance of the first material layer 42 and the second material layer 44 in the distributed Bragg reflector 40 has a respective planar top surface within a horizontal plane overlying the horizontal top surface of the germanium material portion 62.

Subsequently, a silicon capping layer 64 may be formed by performing a selective silicon deposition process such as a selective silicon epitaxy process. The silicon capping layer 64 may grow from, and may be formed on, a physically exposed top surface of the germanium material portion 62. In one embodiment, the duration of the selective silicon deposition process may be selected such that the top surface of the silicon capping layer 64 is formed above the horizontal plane including the top surface of the dielectric capping layer 25. In this embodiment, a vertical surface of the silicon capping layer 64 contacts a sidewall of the dielectric capping layer 25. In one embodiment, each instance of the first material layer 42 and the second material layer 44 in the distributed Bragg reflector 40 has a respective planar top surface within a horizontal plane underlying the horizontal top surface of the silicon capping layer 64.

A photodiode (24, 62, 26) cam be formed, which comprises a germanium material portion 62 laterally extending along a first horizontal direction hd1, a p-doped silicon portion 24, and an n-doped silicon portion 26. In one embodiment, the germanium material portion 62 comprises an angled protrusion portion 62P that protrudes laterally into the distributed Bragg reflector (DBR) 40 with a triangular horizontal cross-sectional shape such that two interfaces between the angled protrusion and the distributed Bragg reflector 40 are adjoined to each other at an angle α in a range from 80 degrees to 100 degrees in a plan view.

The tilt angle of the vertical interfaces between the germanium material portion and the most proximal first material layer 42 within the DBR 40 may be advantageously used to increase the probability of a sequence of two reflections of a photon propagating through the germanium material portion 62 to undergo two consecutive reflections at the two vertical interfaces so that the photon propagates in the opposite direction through the germanium material portion 62 after the two consecutive reflections. This geometry increases the probably of absorption of the photon by the photodetector of the present disclosure. Thus, the photodetector of the present disclosure may increase the probability of a photon capture through the combination of the DBR 40 and the geometry of the dual tilted vertical interfaces between the germanium material portion 62 and the DBR.

In one embodiment, a lateral extent of the angled protrusion portion 62P along the first horizontal direction hd1 is the same as a thickness of an instance of the first material layer 42 that contacts the germanium material portion 62. In one embodiment, each of the two interfaces are located within a respective planar vertical plane, and is adjoined to a respective lengthwise sidewall of the germanium material portion 62 that laterally extends along the first horizontal direction hd1.

In one embodiment, the germanium material portion 62 has a uniform width along a second horizontal direction hd2 that is perpendicular to the first horizontal direction hd1 between a pair of first shallow trench isolation structures 12. In one embodiment, the two first shallow trench isolation structures 12 may be laterally spaced apart from each other by the germanium material portion 62. Each of the two first shallow trench isolation structures 12 contacts a respective lengthwise sidewall of the germanium material portion 62.

The silicon material matrix 10M may embed the two first shallow trench isolation structures 12, the germanium material portion 62, the first p-doped silicon portion 24, and the first n-doped silicon portion 26. In one embodiment, an end surface of the germanium material portion 62 that is perpendicular to the first horizontal direction hd1 is in contact with the silicon material matrix 10M.

In one embodiment, the first p-doped silicon portion 24 and the first n-doped silicon portion 26 are laterally spaced apart from each other along a second horizontal direction hd2 that is perpendicular to the first horizontal direction hd1 by a uniform lateral spacing that is less than a width of the germanium material portion 62 along the second horizontal direction hd2.

The first p-doped silicon portion 24 and the first n-doped silicon portion 26 are embedded within the silicon material matrix 10M, and contacts the germanium material portion 62. In one embodiment, a bottom surface of the germanium material portion 62 comprises: a center surface segment that contacts the silicon material matrix 10M; a first peripheral surface segment that contacts the first p-doped silicon portion 24; and a second peripheral surface segment that contacts the first n-doped silicon portion 26.

In one embodiment, each of the first p-doped silicon portion 24 and the first n-doped silicon portion 26 contacts a respective bottom surface segment of the germanium material portion 62 and a segment of a respective lengthwise sidewall of the germanium material portion 62.

The silicon waveguide 10W may be located over a buried insulating layer 6, and may laterally extend along the first horizontal direction hd1. The silicon material matrix 10M may be adjoined to an end portion of the silicon waveguide 10W, and may embed a germanium material portion 62 that laterally extends along the first horizontal direction hd1 and aligned to the end portion of the silicon waveguide 10W. The distributed Bragg reflector 40 includes multiple periodic repetitions of a unit layer stack including a first material layer 42 and a second material layer 44. Interfaces between vertically-extending portions of material layers (42, 44) within the distributed Bragg reflector 40 are perpendicular to the first horizontal direction hd1. The distributed Bragg reflector 40 is in contact with the germanium material portion 62.

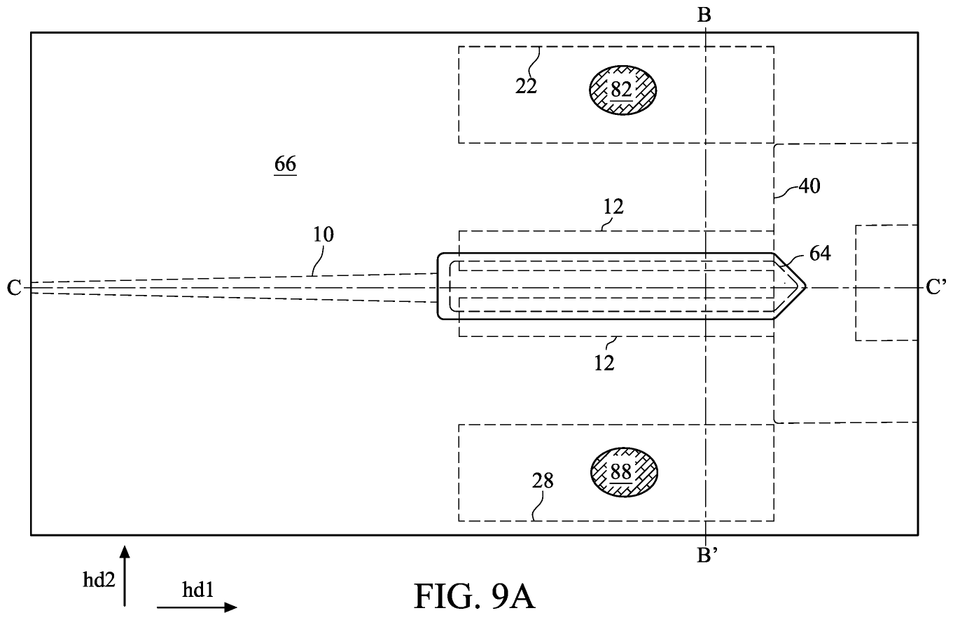

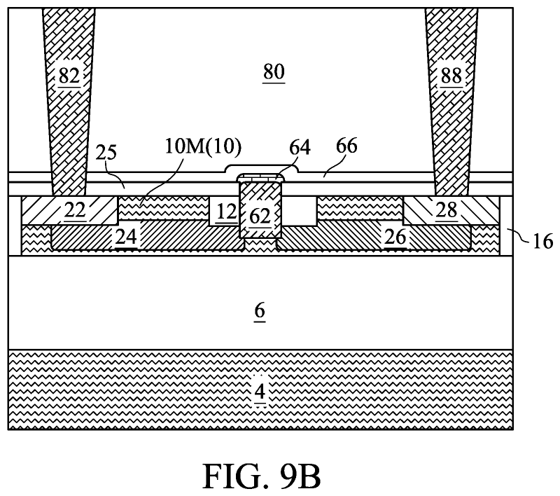

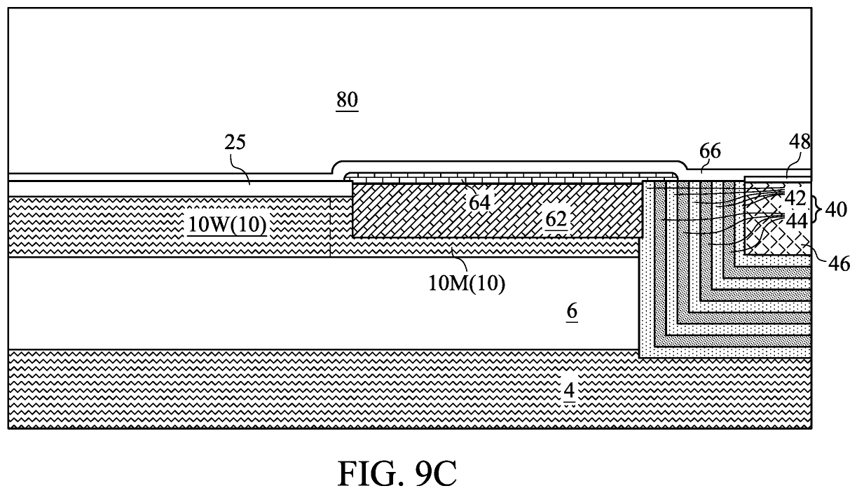

Referring to FIGS. 9A-9C, a dielectric cover layer 66 may be formed above the dielectric capping layer 25, the silicon capping layer 64, and the DBR 40. The dielectric cover layer 66 may comprise silicon oxide or silicon nitride, and may have a thickness in a range from 100 nm to 400 nm, although lesser and greater thicknesses may also be used.

A contact-level dielectric layer 80 may be deposited over the dielectric cover layer 66. The contact-level dielectric layer 80 comprises an interlayer dielectric (ILD) material such as undoped silicate glass, a doped silicate glass, or organosilicate glass, and may have a thickness in a range from 200 nm to 800 nm, although lesser and greater thicknesses may also be used. Contact via structures (82, 88) may be formed through the contact-level dielectric layer 80, the dielectric cover layer 66, and the dielectric capping layer 25. The contact via structures (82, 88) may comprise a first contact via structure 82 contacting the second p-doped silicon portion 22, and a second contact via structure 88 contacting the second n-doped silicon portion 28.

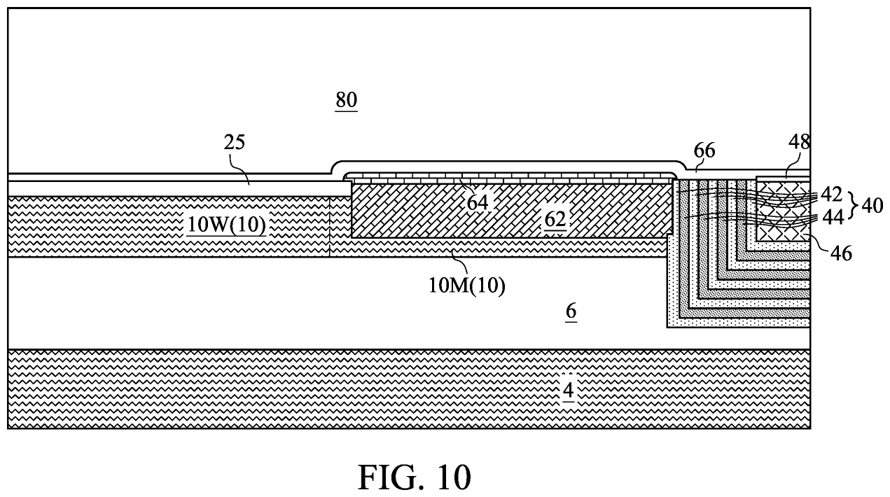

Referring to FIG. 10, an alternative configuration of the exemplary structure is illustrated, which comprises DBR 40 that vertically extends through the silicon material matrix 10M, the buried insulating layer 6, and an upper portion of the handle substrate 4, and contacts a recessed horizontal surface of the handle substrate 4.

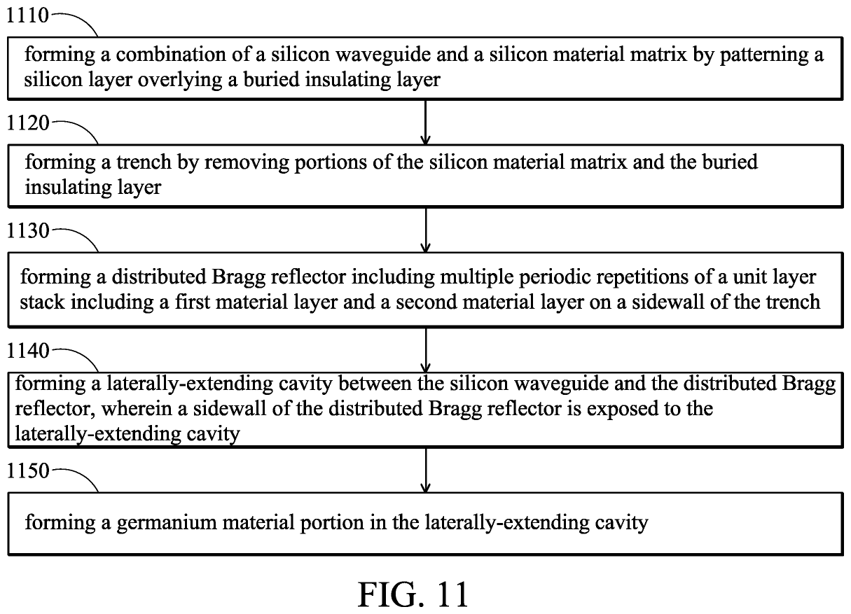

Referring to FIG. 11, a process flow diagram illustrates an exemplary process sequence for forming a semiconductor structure according to an embodiment of the present disclosure.

Referring to step 1110 and FIGS. 1A-2D, a combination of a silicon waveguide 10W and a silicon material matrix 10M may be formed by patterning a silicon layer (such as a top silicon layer 10L) overlying a buried insulating layer 6.

Referring to step 1120 and FIGS. 3A-4C and 10, a trench (such as a reflector-region trench 49) may be formed by removing portions of the silicon material matrix 10M and the buried insulating layer 6.

Referring to step 1130 and FIGS. 5A-6C and 10, a distributed Bragg reflector 40 including multiple periodic repetitions of a unit layer stack including a first material layer 42 and a second material layer 44 may be formed on a sidewall of the trench (such as the reflector-region trench 49).

Referring to step 1140 and FIGS. 7A-7C and 10, a laterally-extending cavity 69 may be formed between the silicon waveguide 10W and the distributed Bragg reflector 40. At least one sidewall (such as a pair of vertical sidewalls) of the distributed Bragg reflector 40 is exposed to the laterally-extending cavity 69.

Referring to step 1150 and FIGS. 8A-8D, 9A-9C, and 10, a germanium material portion 62 may be formed in the laterally-extending cavity 69. The germanium material portion 62 may be a component of a photodiode (24, 62, 26).

Referring to all drawings and according to various embodiments of the present disclosure, a semiconductor device is provided, which comprises: a photodiode (24, 62, 26) comprising a germanium material portion 62 laterally extending along a first horizontal direction hd1, a p-doped silicon portion 24, and an n-doped silicon portion 26; and a distributed Bragg reflector 40 including multiple periodic repetitions of a unit layer stack including a first material layer 42 and a second material layer 44, wherein interfaces between vertically-extending portions of material layers (42, 44) within the distributed Bragg reflector 40 are perpendicular to the first horizontal direction hd1, and wherein the distributed Bragg reflector 40 is in contact with the germanium material portion 62.

In one embodiment, the germanium material portion 62 comprises an angled protrusion portion 62P that protrudes laterally into the distributed Bragg reflector 40 such that two interfaces between the angled protrusion and the distributed Bragg reflector 40 are adjoined to each other at an angle α in a range from 80 degrees to 100 degrees in a plan view. In one embodiment, a lateral extent of the angled protrusion portion 62P along the first horizontal direction hd1 is the same as a thickness of an instance of the first material layer 42 that contacts the germanium material portion 62. In one embodiment, each of the two interfaces are located within a respective planar vertical plane, and is adjoined to a respective lengthwise sidewall of the germanium material portion 62 that laterally extends along the first horizontal direction hd1.

In one embodiment, the germanium material portion 62 has a uniform width along a second horizontal direction hd2 that is perpendicular to the first horizontal direction hd1. In one embodiment, the semiconductor device comprises two shallow trench isolation structures (such as two first shallow trench isolation structures 12) that are laterally spaced apart from each other by the germanium material portion 62, wherein each of the two shallow trench isolation structures (such as the two first shallow trench isolation structures 12) contacts a respective lengthwise sidewall of the germanium material portion 62.

In one embodiment, the semiconductor device comprises a silicon material matrix 10M embedding the two shallow trench isolation structures (such as the two first shallow trench isolation structures 12), the germanium material portion 62, the first p-doped silicon portion 24, and the first n-doped silicon portion 26. In one embodiment, an end surface of the germanium material portion 62 that is perpendicular to the first horizontal direction hd1 is in contact with the silicon material matrix 10M.

In one embodiment, the first p-doped silicon portion 24 and the first n-doped silicon portion 26 are laterally spaced apart from each other along a second horizontal direction hd2 that is perpendicular to the first horizontal direction hd1 by a uniform lateral spacing that is less than a width of the germanium material portion 62 along the second horizontal direction hd2. In one embodiment, each of the first p-doped silicon portion 24 and the first n-doped silicon portion 26 contacts a respective bottom surface segment of the germanium material portion 62 and a segment of a respective lengthwise sidewall of the germanium material portion 62.

According to another aspect of the present disclosure, a semiconductor device is provided, which comprises: a silicon waveguide 10W located over a buried insulating layer and laterally extending along a first horizontal direction hd1; a silicon material matrix 10M adjoined to an end portion of the silicon waveguide 10W and embedding a germanium material portion 62 that laterally extends along the first horizontal direction hd1 and aligned to the end portion of the silicon waveguide 10W; and a distributed Bragg reflector 40 including multiple periodic repetitions of a unit layer stack including a first material layer 42 and a second material layer 44, wherein interfaces between vertically-extending portions of material layers (42, 44) within the distributed Bragg reflector 40 are perpendicular to the first horizontal direction hd1, and wherein the distributed Bragg reflector 40 is in contact with the germanium material portion 62.

In one embodiment, the semiconductor structure comprises a p-doped silicon portion 24 and an n-doped silicon portion 26 that are embedded within the silicon material matrix 10M and contacting the germanium material portion 62. In one embodiment, a bottom surface of the germanium material portion 62 comprises: a center surface segment that contacts the silicon material matrix 10M; a first peripheral surface segment that contacts the first p-doped silicon portion 24; and a second peripheral surface segment that contacts the first n-doped silicon portion 26.

In one embodiment, the germanium material portion 62 comprises an angled protrusion portion 62P that protrudes laterally into the distributed Bragg reflector 40 with a triangular horizontal cross-sectional shape. In one embodiment, the semiconductor structure comprises a dielectric capping layer 25 overlying the silicon material matrix 10M. A horizontal top surface of the germanium material portion 62 contacts a sidewall of the dielectric capping layer 25; and each instance of the first material layer 42 and the second material layer 44 in the distributed Bragg reflector 40 has a respective planar top surface within a horizontal plane overlying the horizontal top surface of the germanium material portion 62.

The various embodiments of the present disclosure may be used to provide a photodetector providing high detection efficiency, low dark current, and high bandwidth. Further, the lateral extent of the photodetector of the present disclosure may be shortened along the lengthwise direction of the germanium material portion 62 due to the reflecting geometry provided by the DBR 40 and the double reflection geometry of a pair of vertical interfaces between the germanium material portion 62 and the most proximal first material layer 42 of the DBR.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph of in different paragraphs, a Markush group including a listing of the two or more elements is also impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a photodiode comprising a germanium material portion laterally extending along a first horizontal direction, a p-doped silicon portion, and an n-doped silicon portion; and
a distributed Bragg reflector including multiple periodic repetitions of a unit layer stack including a first material layer and a second material layer, wherein interfaces between vertically-extending portions of material layers within the distributed Bragg reflector are perpendicular to the first horizontal direction, and wherein the distributed Bragg reflector is in contact with the germanium material portion.

2. The semiconductor device of claim 1, wherein the germanium material portion comprises an angled protrusion portion that protrudes laterally into the distributed Bragg reflector such that two interfaces between the angled protrusion and the distributed Bragg reflector are adjoined to each other at an angle in a range from 80 degrees to 100 degrees in a plan view.

3. The semiconductor device of claim 2, wherein a lateral extent of the angled protrusion portion along the first horizontal direction is the same as a thickness of an instance of the first material layer that contacts the germanium material portion.

4. The semiconductor device of claim 2, wherein each of the two interfaces are located within a respective planar vertical plane, and is adjoined to a respective lengthwise sidewall of the germanium material portion that laterally extends along the first horizontal direction.

5. The semiconductor device of claim 1, wherein the germanium material portion has a uniform width along a second horizontal direction that is perpendicular to the first horizontal direction.

6. The semiconductor device of claim 1, further comprising two shallow trench isolation structures that are laterally spaced apart from each other by the germanium material portion, wherein each of the two shallow trench isolation structures contacts a respective lengthwise sidewall of the germanium material portion.

7. The semiconductor device of claim 6, further comprising a silicon material matrix embedding the two shallow trench isolation structures, the germanium material portion, the p-doped silicon portion, and the n-doped silicon portion.

8. The semiconductor device of claim 7, wherein an end surface of the germanium material portion that is perpendicular to the first horizontal direction is in contact with the silicon material matrix.

9. The semiconductor device of claim 1, wherein the p-doped silicon portion and the n-doped silicon portion are laterally spaced apart from each other along a second horizontal direction that is perpendicular to the first horizontal direction by a uniform lateral spacing that is less than a width of the germanium material portion along the second horizontal direction.

10. The semiconductor device of claim 7, wherein each of the p-doped silicon portion and the n-doped silicon portion contacts a respective bottom surface segment of the germanium material portion and a segment of a respective lengthwise sidewall of the germanium material portion.

11. A semiconductor device comprising:
a silicon waveguide located over a buried insulating layer and laterally extending along a first horizontal direction;
a silicon material matrix adjoined to an end portion of the silicon waveguide and embedding a germanium material portion that laterally extends along the first horizontal direction and aligned to the end portion of the silicon waveguide; and
a distributed Bragg reflector including multiple periodic repetitions of a unit layer stack including a first material layer and a second material layer, wherein interfaces between vertically-extending portions of material layers within the distributed Bragg reflector are perpendicular to the first horizontal direction, and wherein the distributed Bragg reflector is in contact with the germanium material portion.

12. The semiconductor structure of claim 11, further comprising a p-doped silicon portion and an n-doped silicon portion that are embedded within the silicon material matrix and contacting the germanium material portion.

13. The semiconductor structure of claim 12, wherein a bottom surface of the germanium material portion comprises:
a center surface segment that contacts the silicon material matrix;
a first peripheral surface segment that contacts the p-doped silicon portion; and
a second peripheral surface segment that contacts the n-doped silicon portion.

14. The semiconductor structure of claim 11, wherein the germanium material portion comprises an angled protrusion portion that protrudes laterally into the distributed Bragg reflector with a triangular horizontal cross-sectional shape.

15. The semiconductor structure of claim 11, further comprising a dielectric capping layer overlying the silicon material matrix, wherein:
a top surface of the germanium material portion contacts a sidewall of the dielectric capping layer; and
each instance of the first material layer and the second material layer in the distributed Bragg reflector has a respective planar top surface within a horizontal plane overlying the top surface of the germanium material portion.

16. A method of forming a semiconductor structure, the method comprising:
forming a combination of a silicon waveguide and a silicon material matrix by patterning a silicon layer overlying a buried insulating layer;
forming a trench by removing portions of the silicon material matrix and the buried insulating layer;
forming a distributed Bragg reflector including multiple periodic repetitions of a unit layer stack including a first material layer and a second material layer on a sidewall of the trench;
forming a laterally-extending cavity between the silicon waveguide and the distributed Bragg reflector, wherein a sidewall of the distributed Bragg reflector is exposed to the laterally-extending cavity; and
forming a germanium material portion in the laterally-extending cavity.

17. The method of claim 16, wherein:
the silicon waveguide laterally extends along a first horizontal direction; and
the laterally-extending cavity laterally extends along the first horizontal direction and has an end wall that is aligned to the silicon waveguide.

18. The method of claim 16, wherein:
the laterally-extending cavity comprises a notched end portion that cuts through an instance of the first material layer; and
the notched end portion has a triangular horizontal cross-sectional shape.

19. The method of claim 16, wherein:
a p-doped silicon portion and an n-doped silicon portion are embedded within the silicon material matrix; and
the germanium material portion is formed on a peripheral region of the p-doped silicon portion and on a peripheral portion of the n-doped silicon portion.

20. The method of claim 16, further comprising:
forming a dielectric capping layer over the silicon material matrix, wherein the multiple periodic repetitions of the unit layer stack are formed in the trench and over the dielectric capping layer; and
removing portions of the multiple periodic repetitions of the unit layer stack from above a horizonal plane including a top surface of the dielectric capping layer.
